(19) United States
(12) Patent Application Publication
(10) Pub. No.: US 2025/0072019 A1
(43) Pub. Date: Feb. 27, 2025

(54) SCHOTTKY BARRIER DIODE AND METHOD OF MANUFACTURING THE SAME

(71) Applicant: ELECTRONICS AND TELECOMMUNICATIONS RESEARCH INSTITUTE, Daejeon (KR)

(72) Inventors: Jun Hwan SHIN, Daejeon (KR); Young Ho Kim, Daejeon (KR); Eui Su Lee, Daejeon (KR); Jin Chul Cho, Daejeon (KR); Soo Cheol Kang, Daejeon (KR); Dong Woo Park, Daejeon (KR); II Min Lee, Daejeon (KR)

(21) Appl. No.: 18/770,484

(22) Filed: Jul. 11, 2024

(30) Foreign Application Priority Data
Aug. 21, 2023 (KR) 10-2023-0109098

(51) Int. Cl. H01L 29/872; H01L 29/06; H01L 29/20; H01L 29/66

(52) U.S. Cl. CPC H01L 29/872; H01L 29/0649; H01L 29/20; H01L 29/66143

(57) ABSTRACT

Disclosed herein are a Schottky barrier diode (SBD) and a method of manufacturing the same. The SBD includes a substrate, an ohmic layer formed on a portion of an upper portion of the substrate, a Schottky layer formed on a portion of an upper portion of the ohmic layer, an insulating layer formed on a portion of the upper portion of the ohmic layer, a low-k material layer formed on a portion of the upper portion of the substrate, and a Schottky metal layer formed on portions of upper portions of the low-k material layer and the insulating layer.

### CROSS-REFERENCE TO RELATED APPLICATION

This application claims priority to and the benefit of Korean Patent Application No. 10-2023-0109098 filed on Aug. 21, 2023, the disclosure of which is incorporated herein by reference in its entirety.

### BACKGROUND

### 1. Field of the Invention

The present invention relates to a Schottky barrier diode (SBD) and a method of manufacturing the same, and more specifically, to an SBD capable of more effectively responding to terahertz (THz) electromagnetic waves and a method of manufacturing the same.

### 2. Discussion of Related Art

Recently, research is being actively conducted to use Schottky barrier diodes (SBDs) in a millihertz (mHz) to terahertz (THz) wave band. An SBD is generally a two-terminal device with an energy barrier generated by a Schottky junction formed at an interface between a semiconductor and a metal. The SBD is a device that detects an electrical signal proportional to a value of an input signal using rectifying characteristics of a Schottky energy barrier in the device.

Generally, in order for efficient detection in the millimeter wave (mm Wave) to THz wave band, diodes including Schottky barriers made of n-type III-V group semiconductors and metals with high electron mobility are mainly used. SBDs may be used in various fields such as envelope detection, mixers, multipliers, and power amplifiers according to a structure of the device, the number of junctions in the device, and materials constituting the junction. SBDs can be roughly classified into two general types, such as biased SBDs and zero-biased SBDs, according to whether an external bias is applied when a signal is detected.

A GaAs SBD, which is a representative III-V compound-based Schottky barrier diode used in the mHZ to THz wave band, is turned off at a threshold voltage of around 0.7 V due to a potential barrier formed between n-GaAs and a metal junction to exhibit non-linear current-voltage characteristics. Since the GaAs SBD has an electron mobility about 6 times greater than that of Si, GaAs SBDs are used for high-speed switching, detectors, harmonic mixers, and multipliers in a band of tens of gigahertz (GHz) or more. Meanwhile, an InGaAs-based SBD, which is mainly studied as a zero-biased SBD, has high electron mobility characteristics of InGaAs and has a low Schottky barrier of about 0.2 eV due to Fermi level pinning, unlike a height of a Schottky energy barrier between GaAs and a metal, and thus signal detection is possible at a high signal-to-noise ratio (SNR) without a separate external bias. Thus, the number of additional circuits may be reduced when a passive imaging system or wireless communication system is formed, and thereby system complexity can be lowered.

Currently, research and development on a Schottky barrier diode is being conducted to reducing an anode area, a chip size, and parasitic R, L, and C components in order to improve an operating cutoff frequency and responsivity of a Schottky barrier diode. Research is being actively conducted on a planar Schottky diode with a surface channel structure as shown in FIGS. 1 and 2, which exhibits excellent performance in terms of a device integration density, a yield, and process reliability.

The related art of the present invention is disclosed in Korean Registered Patent No. 10-2371319 (Mar. 2, 2022).

### SUMMARY OF THE INVENTION

The present invention is directed to providing a Schottky barrier diode (SBD) in which design constraints of an SBD may be reduced and an internal parasitic capacitance component and an inductance component may be reduced by replacing a free space region (a lower region of an anode finger) formed in a planar SBD with a surface channel structure with a low-k material, and a manufacturing method thereof.

According to an aspect of the present invention, there is provided an SBD including a substrate, an ohmic layer formed on a portion of an upper portion of the substrate, a Schottky layer formed on a portion of an upper portion of the ohmic layer, an insulating layer formed on a portion of the upper portion of the ohmic layer, a low-k material layer formed on a portion of the upper portion of the substrate, and a Schottky metal layer formed on portions of upper portions of the low-k material layer and the insulating layer.

The low-k material may be made of one or more polymers of SU-8, benzocyclobutene, polystyrene, parylene, polyimide, SUEX, and SLA.

The low-k material layer may be formed on the remaining region not including a mesa region including the ohmic layer, the Schottky layer, and the insulating layer.

The ohmic layer and the Schottky layer may each be made of a III-V group compound containing one or more elements of indium (In), phosphorus (P), gallium (Ga), and arsenic (As).

The insulating layer may be made of a material containing one or more of a nitride, an oxide, and a low-k polymer.

The SBD may further include a contact portion passing through the insulating layer to connect the Schottky metal layer and the Schottky layer.

The contact portion may be made of a metal or a conductive oxide, which forms a Schottky contact with the Schottky layer.

The Schottky metal layer may be made of the same material as the contact portion or a material forming an ohmic contact.

The SBD may further include an ohmic metal layer formed on a portion of an upper portion of the ohmic layer.

The ohmic metal layer may be made of a metal or a conductive oxide, which forms an ohmic contact with the ohmic layer and the Schottky layer.

According to another aspect of the present invention, there is provided a method of manufacturing a Schottky barrier diode (SBD) includes forming an ohmic layer on an upper portion of a substrate, forming a Schottky layer on an upper portion of the ohmic layer, etching a portion of the Schottky layer, forming an ohmic metal layer on the etched portion of an upper portion of the ohmic layer, forming an insulating layer on a portion of an upper portion of the Schottky layer, etching a portion of the upper portions of the substrate on which the ohmic layer, the Schottky layer, and the insulating layer are formed, forming a low-k material layer on the etched portion of the upper portion of the substrate, and forming a Schottky metal layer on portions of upper portions of the low-k material layer and the insulating layer.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a cross-sectional view illustrating a structure of a conventional Schottky barrier diode (SBD);

FIG. 2 is a top view illustrating the structure of the conventional SBD;

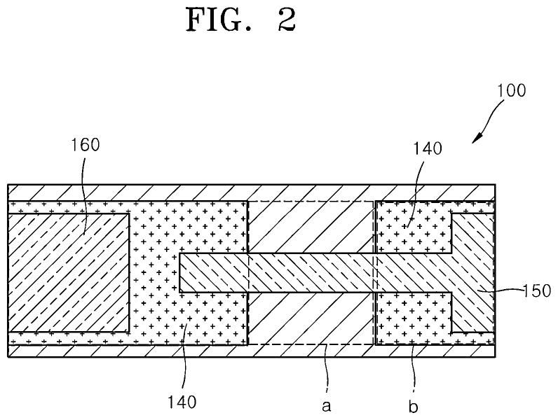

FIG. 3 is a cross-sectional view illustrating an SBD according to one embodiment of the present invention;

FIG. 4 is a top view illustrating the SBD according to one embodiment of the present invention;

FIG. 5 is an exemplary diagram illustrating an equivalent circuit for power coupling characteristics of the conventional SBD;

FIG. 6 is an exemplary diagram illustrating a trade-off relationship between parasitic components according to an increase of a distance between pads in the conventional SBD; and

FIG. 7 is a flowchart illustrating a method of manufacturing an SBD according to one embodiment of the present invention.

### DETAILED DESCRIPTION OF EXEMPLARY EMBODIMENTS

Hereinafter, a Schottky barrier diode (SBD) and a method of manufacturing the same according to embodiments of the present invention will be described in detail with reference to the accompanying drawings. In the following description, thicknesses of lines and sizes of components shown in the drawings may be exaggerated for clarity and convenience of explanation. In addition, the terms described below are defined in consideration of the functions of the present invention, and these terms may be varied according to the intent or custom of a user or an operator. Therefore, these terms should be defined on the basis of the contents throughout the present application.

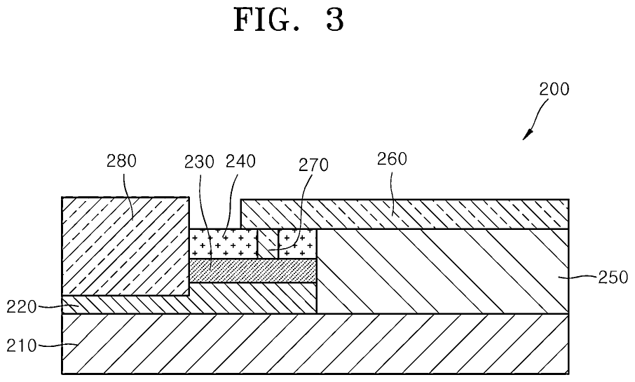

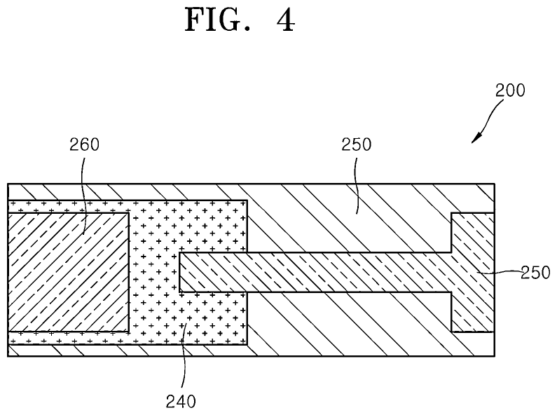

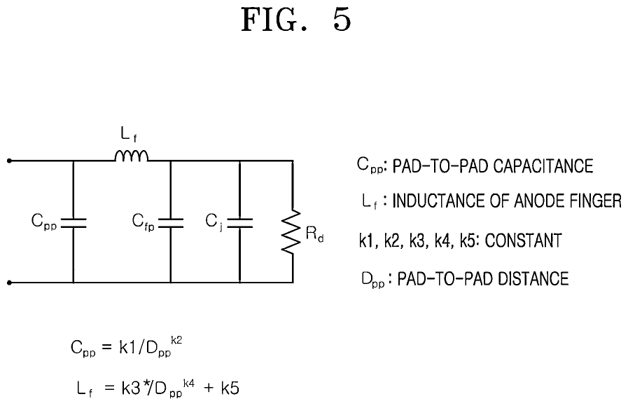

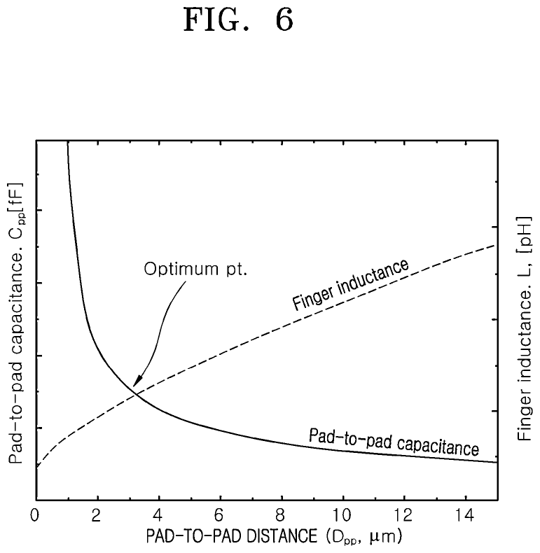

FIG. 3 is a cross-sectional view illustrating a Schottky barrier diode (SBD) according to one embodiment of the present invention, FIG. 4 is a top view illustrating the SBD according to one embodiment of the present invention, FIG. 5 is an exemplary diagram illustrating an equivalent circuit for power coupling characteristics of the conventional SBD, and FIG. 6 is an exemplary diagram illustrating a trade-off relationship between parasitic components according to an increase of a distance between pads in the conventional SBD.

Referring to FIGS. 3 and 4, a Schottky barrier diode (SBD) 200 according to one embodiment of the present invention may include a substrate 210, an ohmic layer 220, a Schottky layer 230, an insulating layer 240, a low-k material layer 250, a Schottky metal layer 260, a contact portion 270, and an ohmic metal layer 280. The SBD according to the embodiment of the present invention may be a planar SBD with a surface channel structure.

The substrate 210 may be a free standing substrate. According to one example, the substrate 210 may be made of a semi-insulating (SI) material.

The ohmic layer 220 may be formed on a portion of an upper portion of the substrate. According to one example, the ohmic layer 220 may be made of a III-V group compound material (semiconductor) containing one or more elements of indium (In), phosphorus (P), gallium (Ga), and arsenic (As).

The Schottky layer 230 may be formed on a portion of an upper portion of the ohmic layer 220. According to one example, the Schottky layer 230 may be made of a III-V group compound material (semiconductor) containing one or more elements of In, P, Ga, and As.

According to one example, the ohmic layer 220 and the Schottky layer 230 may be made of the same material (semiconductor) doped at different concentrations and may have a homojunction structure. For example, the ohmic layer 220 and the Schottky layer 230 may be made of InGaAs doped at different concentrations. According to another example, the ohmic layer 220 and the Schottky layer 230 may be made of different materials (semiconductors) and may have a heterojunction structure.

The insulating layer 240 may be formed on a portion of an upper portion of the Schottky layer 230. According to one example, the insulating layer 240 may be made of a material containing one or more of a nitride, an oxide, and a low-k polymer. For example, the insulating layer 240 may be made of a nitride and/or an oxide containing one or more of SiₓO, SiₓN, SiₓO₁₋ₓN (0≤x≤1), and (Al, Ti, Ga) Ox. As another example, the insulating layer 240 may be made of one or more polymers (i.e., low-k materials) of SU-8, benzocyclobutene, polystyrene, parylene, polyimide, SUEX, and SLA.

The low-k material layer 250 may be formed on a portion of the upper portion of the substrate 210. According to one example, the low-k material layer 250 may be made of a low-k material. For example, the low-k material layer 250 may be made of one or more polymers of SU-8, benzocyclobutene, polystyrene, parylene, polyimide, SUEX, and SLA.

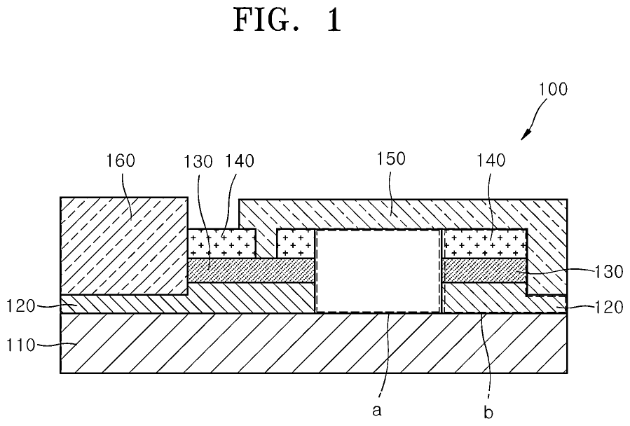

The low-k material layer 250 may be formed on the remaining area not including a mesa area including the ohmic layer 220, the Schottky layer 230, and the insulating layer 240. That is, the low-k material layer 250 may be formed on the remaining area not including the mesa area which includes an anode junction. That is, according to the present embodiment, a free space region (a lower region of the anode finger (see a in FIG. 1)) formed in a planar Schottky barrier diode 100 with a conventional surface channel structure and an area including a portion of the ohmic layer 120, the Schottky layer 130, and the insulating layer 140 (i.e., b in FIG. 1) may be replaced with the low-k material layer 250.

The Schottky metal layer 260 may be formed on a portion of upper portions of the insulating layer 240 and the low-k material layer 250. Although THz detection characteristics of the Schottky metal layer 260 regarding an operating bandwidth are improved as a junction area between the metal and the semiconductor becomes smaller due to the reduction in junction capacitance, the Schottky metal layer 260 may be formed in an appropriate size taking junction area, process difficulty and yield into account. According to one example, the Schottky metal layer 260 may be made of the same material as the contact portion 270, which will be described below, or a material forming an ohmic contact. The Schottky metal layer 260 may correspond to an anode finger.

The contact portion 270 may be formed to pass through the insulating layer 240 and connect the Schottky metal layer 260 to the Schottky layer 230. According to one example, the contact portion 270 may be made of a metal or conductive oxide forming a Schottky contact with the Schottky layer 230.

The ohmic metal layer 280 may be formed on a portion of the upper portion of the ohmic layer 220. According to one example, the ohmic metal layer 280 may be made of a metal or conductive oxide forming an ohmic contact with the ohmic layer 220.

According to the related art, in order to expand an operating frequency bandwidth of the Schottky barrier diode 100, a portion of the area under the anode finger is removed through wet etching to form a free space in the removed region. A Schottky diode with such a structure has an advantage of increasing a cutoff frequency, by means of reducing parasitic capacitance without reducing a chip size. However, the Schottky diodes with such a structure have a problem in that mechanical characteristics of a chip are degraded by an external impact due to the free space formed by an etching process. In addition, in the Schottky diode with the free space, mechanical deformation or damage may occur in the anode finger during wet etching process and post-processing (assembly and package), which may act as a factor in reducing a process yield. According to the present embodiment, the above-described problem can be addressed by replacing the free space, which is formed in the lower portion of the anode finger, with a low-k material.

In addition, according to the present embodiment, by replacing a material of a portion of the conventional SBD (see b in FIG. 1) with a low-k material (e.g., a dielectric material with εᵣ<4) with a dielectric constant of ⅓ to ¼ of a dielectric constant of the material constituting a corresponding layer, an effective dielectric constant for regions a and b can be reduced, and a parasitic capacitance component Cₚₚ generated by a pad-to-pad distance of the SBD can be reduced. Thus, it is possible to increase a magnitude of a voltage and a current response and a bandwidth for the response with respect to an input signal without reducing an anode junction area.

Meanwhile, as shown in FIG. 5, in the conventional SBD in which an anode finger with a length that is longer than or equal to that of region a in FIG. 1 should be formed, capacitance Cₚₚ and inductance Lf of the anode finger depend on a pad-to-pad distance Dₚₚ, and thus the conventional SBD has a trade-off relationship as shown in FIG. 6. Therefore, the conventional SBD has the optimal Cₚₚ and Lf considering such a trade-off relationship (optimum pt in FIG. 6) so that there are limitations in design and process for device implementation.

On the other hand, according to the present embodiment, since the lower portion of the anode finger is filled with a low-k material, the Cₚₚ component is reduced and a trade-off relationship between the parasitic components Cₚₚ-Lf is not established, and thus it is possible to design and process an anode finger with an arbitrary shape and an arbitrary length so that an advantage of expanding a power coupling bandwidth can be achieved.

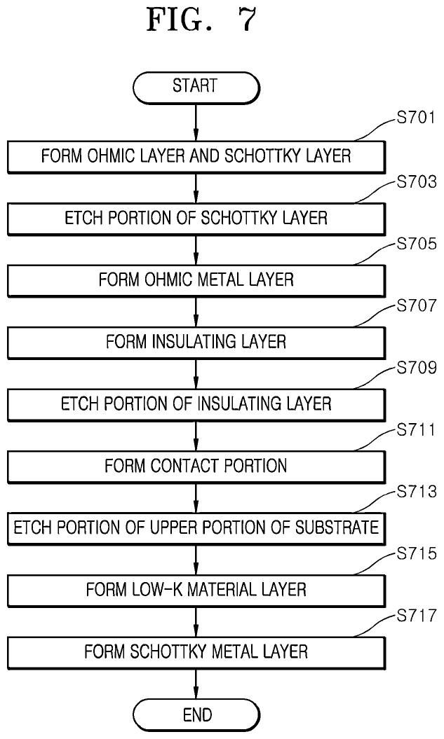

FIG. 7 is a flowchart illustrating a method of manufacturing an SBD according to one embodiment of the present invention.

Hereinafter, the method of manufacturing an SBD according to one embodiment of the present invention will be described with reference to FIG. 7.

First, the ohmic layer 220 and the Schottky layer 230 are sequentially formed on the substrate 210 (S701). Subsequently, a portion of the Schottky layer 230 is etched (S703), and the ohmic metal layer 280 is formed at the corresponding position (i.e., the etched portion of an upper portion of the ohmic layer 220) (S705). In operation S705, the Schottky layer 230 is etched using a phosphoric acid-based solution. In operation S705, thermal processing may be performed after the ohmic metal layer 280 is deposited. The thermal processing may be selectively applied or omitted depending on a process or as necessary. Subsequently, the insulating layer 240 is formed on an upper portion of the Schottky layer 230, not including a region occupied by the ohmic metal layer 280 (S707). Subsequently, a portion of the insulating layer 240 is etched (S709), and the contact portion 270 (anode contact) is formed at the corresponding position (i.e., the etched portion of an upper portion of the Schottky layer 230) (S711). In operation S711, thermal processing may be performed after the contact portion 270 is deposited. The thermal processing may be selectively applied or omitted depending on a process or as necessary. Next, a portion of the upper portion of the substrate 210 on which the ohmic layer 220, the Schottky layer 230, and the insulating layer 240 are formed is etched (S713), and the low-k material layer 250 is formed on the corresponding region (S715). In operation S713, since a portion of the upper portion of the substrate 210 is removed, the ohmic layer 220, the Schottky layer 230, and the insulating layer 240 are mesa-isolated. In operation S715, the low-k material layer 250 is formed as a low-k material layer is applied to the region etched in operation S713. Subsequently, the Schottky metal layer 260 is formed on a portion of upper portions of the insulating layer 240 and the low-k material layer 250 (S717). In operation S717, thermal processing may be performed after the ohmic metal layer 280 is deposited. The thermal processing may be selectively applied or omitted depending on a process or as necessary.

Meanwhile, in the above-described embodiment, although it is described that the ohmic metal layer 280, the insulating layer 240, and the contact portion 270 are formed in this order, the process for forming the ohmic metal layer 280, the insulating layer 240, and the contact portion 270 may be arbitrarily changed. That is, the process sequence may be changed to form the ohmic metal layer 280 and the contact portion 270 after the insulating layer 240 is formed, or the process sequence may be changed to form the insulating layer 240 and the ohmic metal layer 280 after the contact portion 270 is formed.

In addition, in the above-described embodiment, although it is described that the contact portion 270 is formed before the Schottky metal layer 260 is formed, the process may be changed to form the contact portion 270 together with the Schottky metal layer 260. That is, when the Schottky metal layer 260 and the contact portion 270 are made of the same material, the Schottky metal layer 260 and the contact portion 270 may be formed through a single process.

In addition, in the above-described embodiment, although it is described that the ohmic metal layer 280 is formed before the low-k material layer 250 is formed, the process sequence may be changed to form the ohmic metal layer 280 after the low-k material layer 250 is formed or after the Schottky metal layer 260 is formed.

In addition, in the above-described embodiment, although it is described that the insulating layer 240 and the low-k material layer 250 are formed through separate processes, the process may be changed to form the insulating layer 240 together with the low-k material layer 250. That is, when the insulating layer 240 and the low-k material layer 250 are made of the same material, the insulating layer 240 and the low-k material layer 250 may be formed through a single process.

As described above, according to the SBD and the manufacturing method thereof according to one embodiment of the present invention, design limitations in the SBD can be reduced, the parasitic capacitance and inductance components can be reduced, the SBD can operate smoothly in a high frequency band because an operable cutoff frequency of the SBD, the number of process operations of manufacturing the SBD can be reduced, and a yield can be improved during packaging such as flip-chip bonding.

In accordance with the present invention, design limitations in a Schottky barrier diode (SBD) can be reduced. Further, the SBD can operate smoothly in a high frequency band by increasing a cutoff frequency at which the SBD can operate, by means of reducing a parasitic capacitance component and an inductance component.

In accordance with the present invention, process operations of manufacturing the SBD can be reduced, and a yield can be improved during packaging such as flip-chip bonding.

Meanwhile, it should be noted that effects of the present invention are not limited to the above described effect, and other effects of the present invention not described above can be clearly understood by those skilled in the art from the above detailed description.

While the present invention has been described with reference to embodiments shown in the drawings, these embodiments are merely illustrative and it should be understood that various modifications and other equivalent embodiments can be derived by those skilled in the art on the basis of the embodiments. Therefore, the true technical scope of the present invention should be defined by the appended claims.

What is claimed is:

1. A Schottky barrier diode (SBD) comprising:
a substrate;
an ohmic layer formed on a portion of an upper portion of the substrate;
a Schottky layer formed on a portion of an upper portion of the ohmic layer;
an insulating layer formed on a portion of the upper portion of the ohmic layer;
a low-k material layer formed on a portion of the upper portion of the substrate; and
a Schottky metal layer formed on portions of upper portions of the low-k material layer and the insulating layer.

2. The SBD of claim 1, wherein the low-k material is made of one or more polymers of SU-8, benzocyclobutene, polystyrene, parylene, polyimide, SUEX, and SLA.

3. The SBD of claim 1, wherein the low-k material layer is formed on the remaining region not including a mesa region including the ohmic layer, the Schottky layer, and the insulating layer.

4. The SBD of claim 1, wherein the ohmic layer and the Schottky layer are each made of a III-V group compound containing one or more elements of indium (In), phosphorus (P), gallium (Ga), and arsenic (As).

5. The SBD of claim 1, wherein the insulating layer is made of a material containing one or more of a nitride, an oxide, and a low-k polymer.

6. The SBD of claim 1, further comprising a contact portion passing through the insulating layer to connect the Schottky metal layer and the Schottky layer.

7. The SBD of claim 6, wherein the contact portion is made of a metal or a conductive oxide, which forms a Schottky contact with the Schottky layer.

8. The SBD of claim 7, wherein the Schottky metal layer is made of the same material as the contact portion or a material forming an ohmic contact.

9. The SBD of claim 1, further comprising an ohmic metal layer formed on a portion of an upper portion of the ohmic layer.

10. The SBD of claim 9, wherein the ohmic metal layer is made of a metal or a conductive oxide, which forms an ohmic contact with the ohmic layer and the Schottky layer.

11. A method of manufacturing a Schottky barrier diode (SBD), comprising:
forming an ohmic layer on an upper portion of a substrate;
forming a Schottky layer on an upper portion of the ohmic layer;
forming an insulating layer on a portion of an upper portion of the Schottky layer;
etching a portion of the upper portions of the substrate on which the ohmic layer, the Schottky layer, and the insulating layer are formed;
forming a low-k material layer on the etched portion of the upper portion of the substrate; and
forming a Schottky metal layer on a portion of upper portions of the low-k material layer and the insulating layer.

12. The method of claim 11, wherein the low-k material is made of one or more polymers of SU-8, benzocyclobutene, polystyrene, parylene, polyimide, SUEX, and SLA.

13. The method of claim 11, wherein the low-k material layer is formed in the remaining region not including a mesa region including the ohmic layer, the Schottky layer, and the insulating layer.

14. The method of claim 11, wherein the ohmic layer and the Schottky layer are each made of a III-V group compound containing one or more elements of indium (In), phosphorus (P), gallium (Ga), and arsenic (As).

15. The method of claim 11, wherein the insulating layer is made of a material containing one or more of a nitride, an oxide, and a low-k polymer.

16. The method of claim 11, further comprising:
before the forming of the Schottky metal layer,
etching a portion of the insulating layer; and
forming a contact portion on the etched portion of an upper portion of the Schottky layer.

17. The method of claim 16, wherein the contact portion is made of a metal or a conductive oxide, which forms a Schottky contact with the Schottky layer.

18. The method of claim 17, wherein the Schottky metal layer is made of the same material as the contact portion or a material forming an ohmic contact.

19. The method of claim 11, further comprising:
before the forming of the insulating layer,
etching a portion of the Schottky layer; and
forming an ohmic metal layer on the etched portion of an upper portion of the ohmic layer.

20. The method of claim 19, wherein the ohmic metal layer is made of a metal or a conductive oxide, which forms an ohmic contact with the ohmic layer and the Schottky layer.
